(19) United States
(12) Patent Application Publication
(10) Pub. No.: US 2007/0099355 A1
(43) Pub. Date: May 3, 2007

(54) Satellite and method of manufacturing a semiconductor film using the satellite

(75) Inventor: Yoshihiko Hanamaki, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Mitsubishi Electric Corporation, Tokyo (JP)

(21) Appl. No.: 11/453,981

(22) Filed: Jun. 16, 2006

(30) Foreign Application Priority Data
Oct. 28, 2005 (JP) 2005-315165

(51) Int. Cl. H01L 21/84

(52) U.S. Cl. 438/149

(57) ABSTRACT

A method of manufacturing a semiconductor film including a setting a substrate on a satellite; and a forming an alloy semiconductor thin film containing at least two different group V elements or group IV elements on the substrate by metal organic chemical vapor deposition while supplying thermal energy to the substrate through the satellite. The satellite comprises a flat satellite body on which the substrate is placed and a perimeter fixing section which fixes the perimeter of the substrate. The perimeter fixing section contacts only part of the perimeter of the substrate, instead of the entire perimeter of the substrate.

### BACKGROUND OF THE INVENTION

1. Field of the Invention

The present invention relates to a method of manufacturing a semiconductor and a satellite used therefor, when forming an alloy semiconductor thin film containing at least two kinds of group V elements or group IV elements on a substrate using metal organic chemical vapor deposition, capable of making an in-plane distribution of the thin film composition uniform.

2. Background Art

A semiconductor optical element such as a semiconductor laser is manufactured by causing a compound semiconductor crystal to grow on an InP substrate or GaAs substrate. Typical examples of compound semiconductor include a II-IV compound semiconductor which combines group II atoms and group IV atoms and a III-V compound semiconductor which combines group III atoms and group V atoms. There are also alloy semiconductors of various compositions combining a plurality of group II/III atoms and group IV/V atoms. Examples of alloy semiconductors include ZnMgSSe, InGaAsP, GaAsP, ZnSSe, GaPN, GaNAs.

One of processes in which crystals of these alloy semiconductors grow on an InP substrate or GaAs substrate is a metal organic chemical vapor deposition (MOCVD). In this MOCVD, a substrate on which a crystal is grown is set on a satellite inside a reactor of the MOCVD apparatus. This satellite contacts the substrate, and thermal energy is added to the substrate through this satellite and a crystal is grown with the temperature of the substrate (growth temperature) set to, for example, 700° C.

Furthermore, as raw materials, for example, trimethyl indium (TMI), trimethyl gallium (TMG), trimethyl aluminum (TMA), phosphin (PH₃), arsine (AsH₃), silane (SiH₄), diethyl zinc (DEZn) are supplied into the reactor. These raw materials are decomposed by heat and a compound semiconductor crystal which consists of Al, Ga, In, As, P is grown on the substrate. In this case, the composition of the respective layers is adjusted by adjusting the gas flow rates of the raw materials using a massflow controller.

Here, FIG. 14 is a top view of a substrate set on a conventional satellite and FIG. 15 is a section view along a line A-A′ of FIG. 14. A conventional satellite 11 is provided with a perimeter fixing section 11c which fixes the perimeter of the substrate to prevent the substrate 12 from dropping so as to contact the total 360° circumference of the substrate 12.

However, it is a known fact that the conventional apparatus for crystal growth has a difficulty in supplying thermal energy from the satellite to the substrate uniformly, and the temperature at an end of the substrate is higher than that in the center of the substrate (see, for example, Journal of Crystal Growth Vol. 266 P340-P346).

### SUMMARY OF THE INVENTION

The composition ratio of group II/III atoms and group IV/V atoms in an alloy semiconductor is very sensitive to a growth temperature. For this reason, if a crystal is grown in a condition where there is a temperature distribution inside the substrate surface, a composition distribution reflecting the temperature distribution may be produced inside the substrate surface. This tendency is more noticeable in group IV/V atoms than group II/III atoms. Therefore, in the growth of, for example, InGaAsP containing two types of group V atoms, the composition ratio of P at an end of the substrate is greater than in the center of the substrate as a result of reflecting a temperature distribution inside the surface of the substrate, causing an optical band gap to increase. Therefore, using this semiconductor for an active layer of the optical element produces a distribution of a light-emitting wavelength of the optical element inside the substrate surface, resulting in a problem that expected light emitting wavelength conditions cannot be satisfied.

The present invention has been implemented to solve the above described problems, and it is an object of the present invention to provide a method of manufacturing a semiconductor and a satellite used therefor when forming an alloy semiconductor thin film containing at least two kinds of group V elements or group IV elements on a substrate using metal organic chemical vapor deposition, capable of making an in-plane distribution of the composition of the thin film uniform.

According to one aspect of the present invention, a method of manufacturing a semiconductor including a step of setting a substrate on a satellite; and a step of forming an alloy semiconductor thin film containing at least two kinds of group V elements or group IV elements on the substrate using metal organic chemical vapor deposition while supplying thermal energy to the substrate through the satellite, wherein the satellite comprises a flat satellite body on which the substrate is placed and a perimeter fixing section which fixes the perimeter of the substrate and the perimeter fixing section only partially contacts the perimeter of the substrate, instead of the total 360° circumference thereof.

When an alloy semiconductor thin film containing at least two kinds of group V elements or group IV elements on a substrate using metal organic chemical vapor deposition, the present invention can make an in-plane distribution of the composition of the thin film uniform.

Other and further objects, features and advantages of the invention will appear more fully from the following description.

### BRIEF DESCRIPTION OF THE DRAWINGS

FIG. 1 is a top view of a substrate set on a satellite according to First Embodiment of the present invention.

FIG. 2 is a section view along a line A-A′ of FIG. 1.

FIG. 3 is a section view along a line B-B′ of FIG. 1.

FIG. 4 is a perspective view showing an example of the finished semiconductor laser.

FIG. 5 shows a PL (Photoluminescence) wavelength distribution of the active layer of a semiconductor optical element which has been grown using the satellite according to First Embodiment of the present invention.

FIG. 6 shows a PL wavelength distribution of the active layer of a semiconductor optical element which has been grown using a conventional satellite

FIG. 7 is a top view of a satellite whose perimeter fixing section including 3 lugs.

FIG. 8 is a top view of a satellite whose perimeter fixing section including 5 lugs.

FIG. 9 is a top view of a satellite whose perimeter fixing section including 6 lugs.

FIG. 10 is a top view of a satellite whose perimeter fixing section including 7 lugs.

FIG. 11 is a top view of a satellite whose perimeter fixing section including 8 lugs.

FIG. 12 shows a column-shaped screw.

FIG. 13 shows a quadratic prism-shaped screw.

FIG. 14 is a top view of a substrate set on a conventional satellite.

FIG. 15 is a section view along a line A-A′ of FIG. 14.

### DETAILED DESCRIPTION OF THE PREFERRED EMBODIMENTS

### First Embodiment

With reference now to the attached drawings, the method of manufacturing a semiconductor according to First Embodiment of the present invention will be explained below.

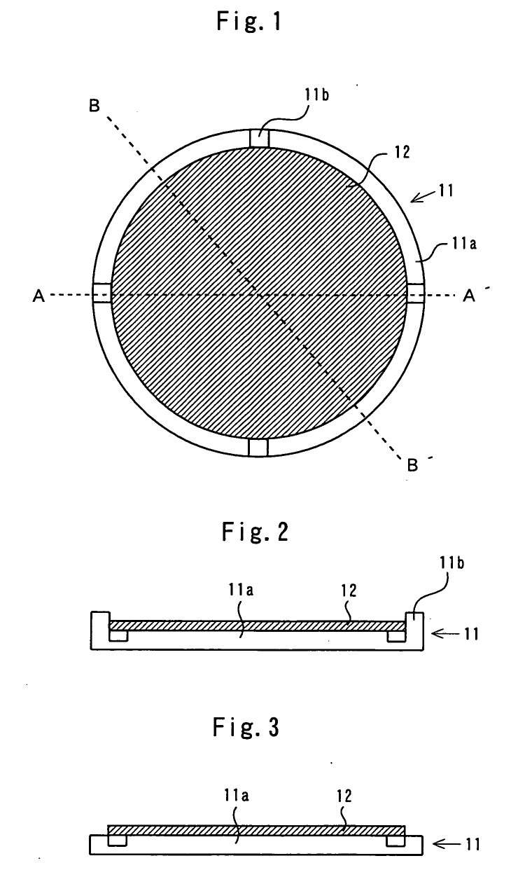

First, as shown in FIG. 1, a substrate 12 is set on a satellite 11. FIG. 2 is a section view along a line A-A′ of FIG. 1 and FIG. 3 is a section view along a line B-B′ of FIG. 1. The satellite 11 has a flat satellite body 11a on which the substrate 12 is placed and a perimeter fixing section 11b which fixes the perimeter of the substrate 12. In FIG. 1, the perimeter fixing section 11b consists of four lugs. The perimeter fixing section 11b only partially contacts the perimeter of the substrate 12, instead of the total 360° circumference thereof. Furthermore, the satellite 11 is provided on a susceptor and rotates.

Next, an alloy semiconductor thin film containing at least two kinds of group V elements or group IV elements is formed on the substrate 12 while supplying thermal energy to the substrate 12 through the satellite 11 using metal organic chemical vapor deposition.

More specifically, as shown in Table 1, a buffer layer made of n-type GaAs or AlGaAs doped with Si, a clad layer made of n-type AlGaInP, a guide layer made of InGaP doped with no impurities, an active layer made of GaAsP, an InGaP guide layer doped with no impurities, a P-type AlGaInP clad layer doped with Zn, a BDR (Band Discontinuity Reduction) layer made of P-type InGaP and a contact layer made of GaAs are grown one by one on an n-type GaAs substrate.

TABLE 1

| | | | Carrier | |
|---|---|---|---|---|
| | | | concentration | Thickness |
| Name of layer | Material | Impurity | (10¹⁸/cm³) | (nm) |
| Contact layer | GaAs | Zn | 10-30 | 100-500 |
| BDR | InGaP | Zn | 1.0-3.0 | 20-100 |
| p-clad layer | AlGaInP | Zn | 1.0-2.0 | 500-1500 |
| Guide layer | InGaP | — | — | 500-1500 |
| Active layer | GaAsP | — | — | 5-12 |
| Guide layer | InGaP | — | — | 500-1500 |
| n-clad layer | AlGaInP | Si | 0.5-1.5 | 500-1500 |
| Buffer layer | GaAs | Si | 0.5-1.5 | 200-700 |
| Substrate | GaAs | Si | — | — |

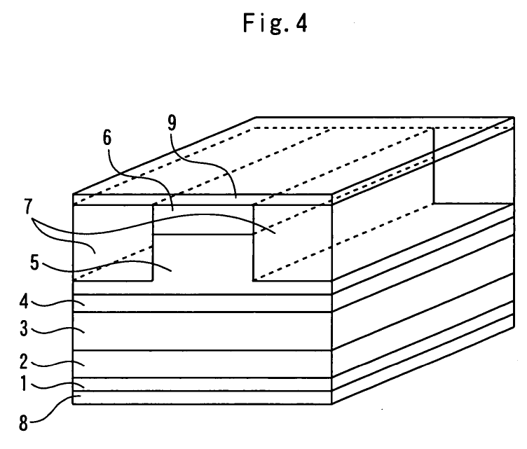

FIG. 4 is a perspective view showing an example of the finished semiconductor laser. An n-type buffer layer 2, n-type clad layer 3, quantum well structure 4, p-type contact layer 5 and p-type cap layer 6 are formed on an n-type substrate 1, and an n-type current block layer 7 is formed on both sides of the p-type contact layer 5 and p-type cap layer 6. An n-type electrode 8 is then formed beneath the n-type substrate 1 and a p-type electrode 9 is formed on the p-type cap layer 6.

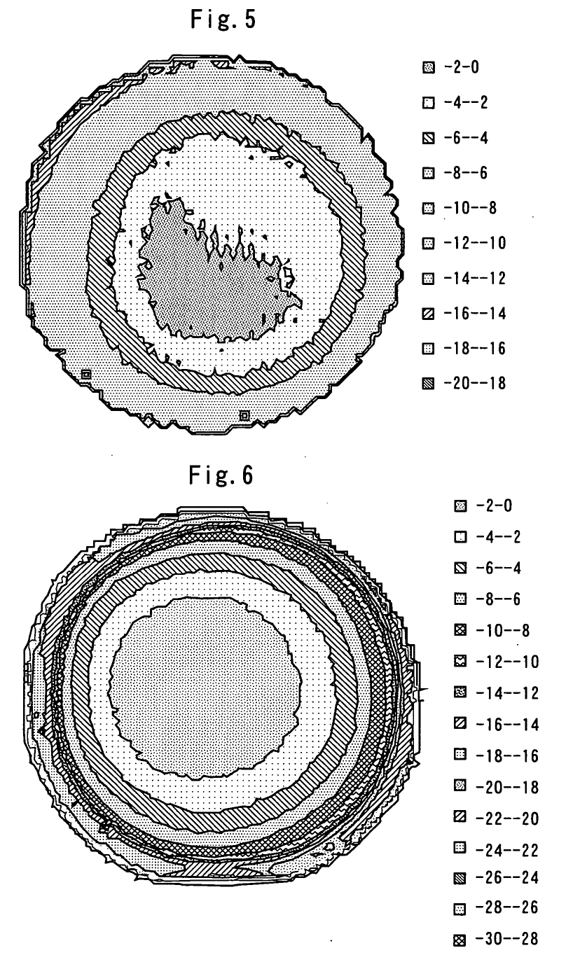

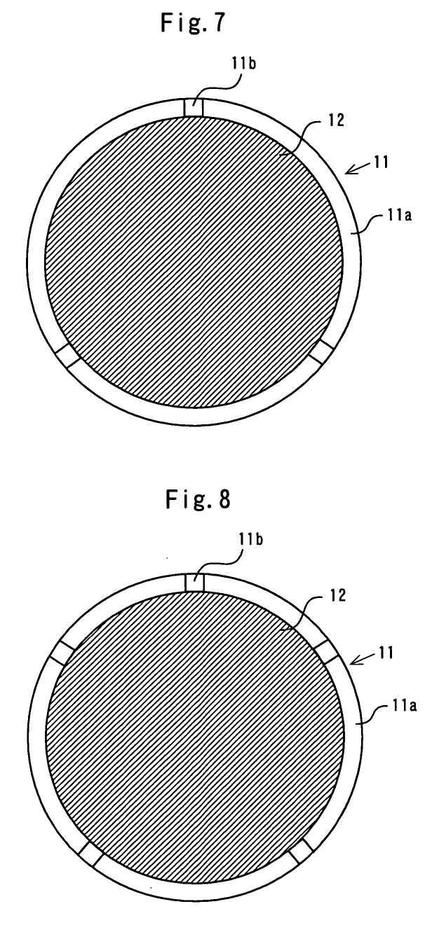

FIG. 5 shows a PL (Photoluminescence) wavelength distribution of the active layer of a semiconductor optical element which has been grown using the satellite according to First Embodiment of the present invention, and FIG. 6 shows a PL wavelength distribution of the active layer of a semiconductor optical element which has been grown using a conventional satellite. These figures show relative wavelengths with respect to the central wavelength. It is appreciated from this result that the wavelength distribution is improved by approximately 10 nm when the satellite according to this embodiment is used compared with the case where the conventional satellite is used, and it is possible to thereby make the in-plane distribution of the composition of the active layer of the semiconductor optical element uniform.

Therefore, when an alloy semiconductor thin film containing at least two kinds of group V elements or group IV elements is formed on a substrate using metal organic chemical vapor deposition, the use of the satellite which only partially contacts the perimeter of the substrate, instead of the total 360° circumference thereof can make the in-plane distribution of the composition of the thin film uniform. In this way, many semiconductor optical elements having the same light emitting wavelength (lasing wavelength) can be manufactured from one substrate, which improves yields of manufacturing semiconductor optical elements.

However, fixing the substrate on the satellite and effectively lowering the substrate temperature around the satellite require the perimeter fixing section to contact 10 to 80% or more preferably 10 to 40% of the perimeter of the substrate.

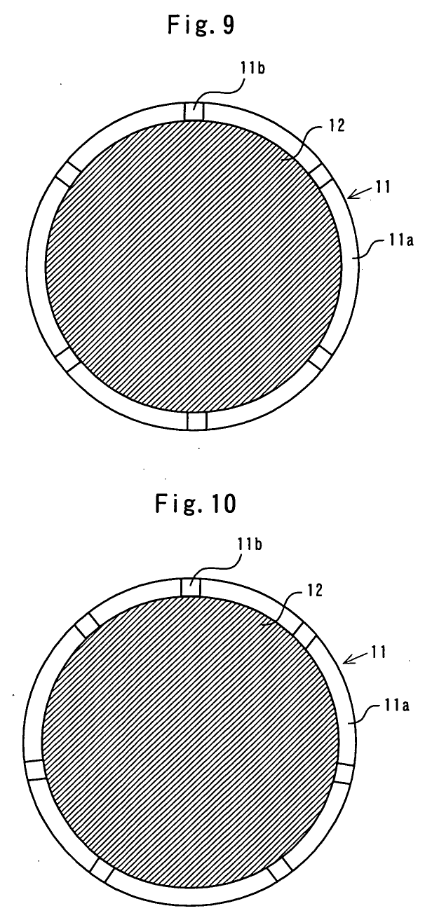

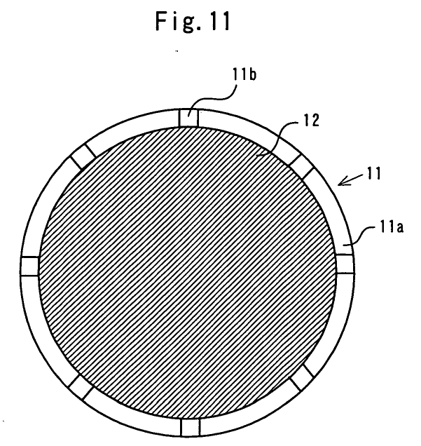

Furthermore, FIG. 1 shows an example with four lugs, but there may also be cases where the number of lugs is three as shown in FIG. 7, the number of lugs is five as shown in FIG. 8, the number of lugs is six as shown in FIG. 9, the number of lugs is seven as shown in FIG. 10 or the number of lugs is eight as shown in FIG. 11. That is, a satellite having the perimeter fixing section including 3 to 8 lugs can be used. This is because it is not possible to fix a wafer on the satellite with only two lugs, while the temperature around the satellite cannot be effectively lowered with nine or more lugs.

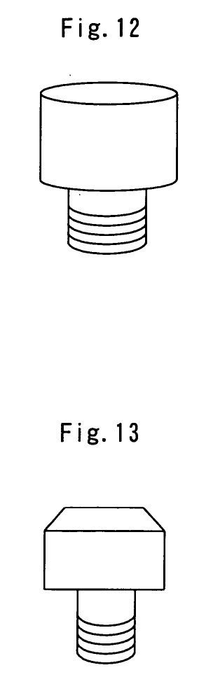

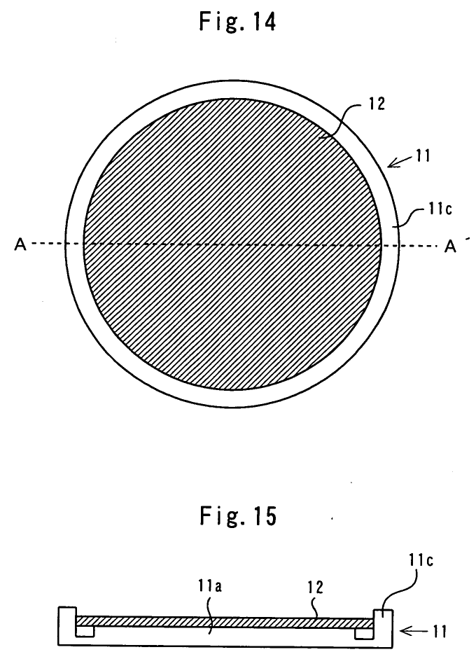

The satellite body is generally made of carbon and the perimeter fixing section is formed by cutting the satellite body. The satellite may also be formed by attaching screws to the satellite body which is flat with no lugs as the perimeter fixing section. This makes it possible to flatten the satellite body, which is advantageous in volume production of satellites. In this case, column-shaped or quadratic prism-shaped screws can be used as shown in FIGS. 12, 13 respectively. As the materials of the screws, any one of carbon as in the case of the satellite, SiO₂ (quartz) or BN (boron nitride) can be used. Furthermore, the length of the screw section is shorter than the thickness of the satellite and the screw head has the same thickness as that of the perimeter fixing section.

The above-mentioned embodiment has explained a semiconductor optical element containing GaAsP in its active layer as an example, but the present invention is also applicable to all semiconductor optical elements in general using an alloy semiconductor having at least two kinds of group V elements or group IV elements such as ZnMgSSe, InGaAsP, GaAsP, ZnSSe, GaPN, GaNAs.

### Second Embodiment

Second Embodiment will use a satellite which fixes a substrate by means of electrostatic chuck or vacuum suction. This makes it possible to flatten the satellite body, which is advantageous in volume production of satellites.

Here, the electrostatic chuck is designed such that a dielectric layer is provided on the satellite, a voltage is applied between the satellite and substrate and the substrate is fixed on the satellite by a force generated between the satellite and substrate. The technique of the electrostatic chuck is widely known but there is no example where this technique is applied to an MOCVD apparatus.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2005-315165, filed on Oct. 28, 2005 including specification, claims, drawings and summary, on which the Convention priority of the present application is based, are incorporated herein by reference in its entirety.

1. A method of manufacturing a semiconductor film comprising:
setting a substrate on a satellite; and
forming an alloy semiconductor thin film containing at least two different group V elements or group IV elements on the substrate by metal organic chemical vapor deposition while supplying thermal energy to the substrate through the satellite, wherein the satellite comprises
a flat satellite body on which the substrate is placed
and a perimeter fixing section which fixes the perimeter of the substrate, the perimeter fixing section only partially contacting the perimeter of the substrate, not all of the perimeter of the substrate.

2. The method of manufacturing a semiconductor film according to claim 1, wherein the perimeter fixing section contacts 10 to 80% of the perimeter of the substrate.

3. The method of manufacturing a semiconductor film according to claim 1, wherein the perimeter fixing section includes 3 to 8 lugs.

4. The method of manufacturing a semiconductor film according to claim 1, including forming the perimeter fixing section by cutting the satellite body.

5. The method of manufacturing a semiconductor film according to claim 1, wherein the satellite body includes screws as the perimeter fixing section.

6. The method of manufacturing a semiconductor film according to claim 5, wherein the screws are column-shaped or quadratic prism-shaped.

7. The method of manufacturing a semiconductor film according to claim 5, wherein the screws are made from the group consisting of carbon, quartz, and boron nitride.

8. A method of manufacturing a semiconductor film comprising:
setting a substrate on a satellite; and
forming an alloy semiconductor thin film containing at least two different group V elements or group IV elements on the substrate by metal organic chemical vapor deposition while supplying thermal energy to the substrate through the satellite, wherein the satellite fixes the substrate with an electrostatic chuck or vacuum suction.

9. A satellite for supplying thermal energy to a substrate when the substrate is set on the satellite during crystal growth and an alloy semiconductor thin film containing at least two different group V elements or group IV elements is formed on the substrate by metal organic chemical vapor deposition, comprising:
a flat satellite body on which the substrate is placed; and
a perimeter fixing section which fixes the perimeter of the substrate, wherein the perimeter fixing section only partially contacts the perimeter of the substrate, not all of the perimeter of the substrate.

10. The satellite according to claim 9, wherein the perimeter fixing section contacts 10 to 80% of the perimeter of the substrate.

11. The satellite according to claim 9, wherein the perimeter fixing section includes 3 to 8 lugs.

12. The satellite according to claim 9, wherein the perimeter fixing section is formed by cutting the satellite body.

13. The satellite according to claim 9, wherein the satellite body includes screws as the perimeter fixing section.

14. The satellite according to claim 13, wherein the screws are column-shaped or quadratic prism-shaped.

15. The satellite according to claim 13, wherein the screws are made of material selected from the group consisting of carbon, quartz, and boron nitride.

16. A satellite for supplying thermal energy to a substrate when the substrate is set on the satellite during crystal growth and an alloy semiconductor thin film containing at least two different group V elements or group IV elements is formed on the substrate by metal organic chemical vapor deposition, wherein the substrate is fixed by an electrostatic chuck or vacuum suction.
